(19) United States
(12) Patent Application Publication
(10) Pub. No.: US 2002/0196685 A1
(43) Pub. Date: Dec. 26, 2002

(54) Trusted and verifiable data storage system, method, apparatus and device

(76) Inventor: Andrew Topham, Gloucestershire (GB)

Correspondence Address: LOWE HAUPTMAN GILMAN & BERNER, LLP, Suite 310, 1700 Diagonal Road, Alexandria, VA, 22314, US

(21) Appl. No.: 10/162,704

(22) Filed: Jun. 6, 2002

(30) Foreign Application Priority Data
Jun. 9, 2001 (GB) 0114115.9

(51) Int. Cl. G11C 7/00

(52) U.S. Cl. 365/200

(57) ABSTRACT

A data set is stored in a data storage medium by determining a checksum value of the data set. The checksum value is substantially unique to the data set. Trusted time stamp data forming a receipt data are obtained by applying an encryption to the checksum value and the trusted time stamp data, such that the receipt data form an encrypted data packet. The data set and receipt data are stored on the data storage medium.

### FIELD OF THE INVENTION

The present invention relates to the field of data storage.

### BACKGROUND TO THE INVENTION

Known data back up storage systems for back up of individual computers, or networks of computers include tape data storage devices, for example digital data storage (DDS) format devices, and CD-ROM data storage devices. Back up tapes and CD-ROMs can be transported away from the site of a host computer or computer installation, for safe keeping.

Prior art back up programs, either as application programs, or as part of an operating system such as Windows 2000®, provide for periodic back up of full data sets comprising all data on the computer, or partial data sets, including delta back ups, being files which have changed since a last back up operation. With conventional back up programs, a time and date at which a back up operation was made is added to the data storage medium, so that when the data storage medium is re-read by a computer system, the vintage of the back up data can be determined.

By having a back up data set stored on a removable data storage medium, if there is a hard disc failure or other catastrophe which results in loss of data on the host computer, or loss of the whole host computer including loss of data, then the data can be restored to the same or a new host computer by loading it back from the back up data storage medium. The data will be recovered from the back up data storage medium to a same state as the one at the time and date in which the data was originally stored to the back up data storage medium. Depending upon the regularity of back up operations, that state could be hours old, days old, or a week or more old, and any changes to the data state of the host computer occurring between the time of back up and the time of catastrophe may be lost.

For many businesses, data back ups contain a permanent record of data that is critical for that business. Additionally, they provide a periodic snapshot of how that data developed at a point in time. In many cases, periodically stored computer back up tapes provide the only record of how the organizations data systems have developed over time. The back up data storage medium can therefore provide a valuable resource for helping to resolve any disputes surrounding data at a previous time which was recorded by the host computer systems of a business. Such disputes typically may include legal disputes, for example back up data may be used for the purpose of establishing copyright in a computer program, or for recording the first putting into practice of a new invention, the details of which may have been recorded on a hard disc on a host computer, or for evidencing a series of e-mails, which have been stored on a back up data storage medium from an e-mail server.

While historical back ups of data are routinely made, for the purpose of evidencing legal disputes they have the drawback that the data on a re-writeable data storage medium such as a tape is simple to fabricate at a later date, and may not satisfy the legal criteria to establish that the data stored on the back up medium was actually stored at the date claimed.

EP 0940945 discloses a method of producing a document fingerprint, comprising a cryptographic hash function, producing a document certificate comprising the document fingerprint and a time stamp, applying a second cryptographic hash function, and signing the certificate fingerprint to produce an additional signature. The original electronic document can be stored. EP 0940945 deals with individual documents only, and does not store contextual information relating individual documents to other documents

U.S. Pat. No. 5,347,579 discloses a non modifiable reference data which can be used to authenticate an original electronic diary entry. Archived computer diary records are time stamped and authenticated, and permanently stored.

WO 92/03000 disclosure a method for secure time stamping of digital documents in which a system for time stamping a digital document protects the secrecy of the document text and provides a tamper proof time seal establishing an authors claim to the temporal existence of a document. A time stamping authority applies a cryptographic signature to a composite receipt, which is transmitted to the author.

WO 99/13415 discloses a medical image management system which applies to a local time stamp authority, to authenticate image information which can be stored in a picture archiving system.

### SUMMARY OF THE INVENTION

Specific implementations according to the present invention aim to provide a trusted back up data storage format, which has the characteristics that any data stored onto a back up data storage medium is time and date stamped with a coding which is verifiable. Preferably the time/date stamp is independently verifiable by a third party organization. At a time of creating a back up data set, a time and date stamp is sought automatically from an independent trusted provider of time stamps. The time stamp provider provides a time stamp data which is unique to a data set stored, and which contains coded time and date information. The time stamp is stored on the data storage medium along with the data set as an encoded receipt data.

Upon reading the data storage medium at a later date, the receipt can be sent to a trusted computer, which verifies the time and date data correspond to the data set stored on the data storage medium.

The specific implementations described herein provide for the securing of an intact data set. This has value in establishing a set of relationships between documents comprising the data set.

Further, the specific implementations disclosed herein provide for creating a verifiable data history which is stored on a removable storage media, this provides an ability to secure multiple verifiable instances of a data set, recording a development and evolution of a data set on a computer or computer system.

By providing a removable data storage media having a receipt data comprising a trusted time stamp and a checksum value of a data set stored on the data storage media, a permanent record of a data state of a computer or computer system can be stored. Consequently, when the computer or computer system has changed its data state through normal use, the stored data set and receipt can be independently verified retrospectively, to be a correct data state of the computer or computer system at an earlier time.

Within a data set, the information that individual files are stored contemporaneously with other files may be important in seftirig the context for showing the particular is of a certain age, or for evidencing the circumstances of the creation of that file.

According to first aspect of the present invention there is provided a method of storing a data set to a data storage medium, said method comprising:

determining a checksum value of said data set, said checksum value substantially unique to said data set;

obtaining a trusted time stamp data;

forming a receipt data by applying an encryption to said checksum value and said trusted time stamp data, such that said receipt data forms an encrypted data packet;

storing said data set on a said data storage medium; and

storing said receipt data on said data storage medium.

According to second aspect of the present invention there is provided a method for verifying a time of storage of a data set stored on a data storage medium, said method comprising:

reading said data set from said data storage medium;

determining a first checksum data from said data set, said first checksum data substantially uniquely describing said data set;

extracting an encrypted receipt data from said data storages medium;

decrypting said receipt data to obtain a second checksum data, and a time data;

comparing said first checksum data with said second checksum data; and

if said second checksum data corresponds with said first checksum data, generating a verification data verifying that said time data corresponds with said data set.

The invention includes a method of storing a data set to a data storage medium, said method comprising:

determining a checksum value of said data set, said checksum value being substantially unique to said data set;

storing said data set on said data storage medium;

storing a receipt data to said data storage medium, said receipt data comprising said checksum value, and a trusted time stamp data.

The invention includes a method of verifying a time of storage of a data set stored on a data storage medium, said method comprising:

reading said data set from said data storage medium;

determining a first checksum value from said data set, said first checksum value substantially uniquely describing said data set;

reading an encrypted receipt data from said data storage medium;

sending said first checksum data and said receipt data to a trusted computer.

The invention includes a method of verifying whether a receipt data corresponds to a data set, said method comprising the steps of:

receiving a first checksum value, said first checksum value substantially uniquely describing said data set;

receiving a receipt data containing a second checksum value and a time stamp data;

comparing said first checksum value and said second checksum value;

generating a verification data depending upon a result of said comparison of said first and second checksum values, wherein if said first checksum value corresponds with said second checksum value, a positive verification data is generated, and if said first checksum value does not correspond with said second checksum value, a negative verification data is generated.

According to third aspect of the present invention there is provided a data storage system for storing a data set to a data storage medium, said system comprising:

a checksum generator for generating a checksum value of said data set, said checksum value substantially unique to said data set;

a trusted time stamp generator for generating a trusted time stamp data;

a receipt generator for forming a receipt data by applying an encryption to said checksum value and said trusted time stamp data, such that said receipt data forms an encrypted data packet; and

a write channel for storing said data set on a said data storage medium and storing said receipt data on said data storage medium.

According to a fourth aspect of the present invention there is provided a system for verifying a time of storage of a data set stored on a data storage medium, said system comprising:

a read channel for reading said data set from said data storage medium;

a checksum generator for generating a first checksum data from said data set, said first checksum data substantially uniquely describing said data set, said read channel operable to read an encrypted receipt data from said data storage medium;

a decryptor for decrypting said receipt data to obtain a second checksum data, and a time data;

a compare component for comparing said first checksum data with said second checksum data; and

a verification data generator operable such that if said second checksum data corresponds with said first checksum data, said verification data generator generates a verification data verifying that said time data corresponds with said data set.

The invention includes a data storage device for storing a verified data set to a data storage medium, said device comprising:

a checksum generator for generating a checksum value! of said data set, said checksum value substantially unique to said data set; and

a write channel for storing said data set on said data storage medium; and

storing a receipt data to said data storage medium, 3aid receipt data comprising said checksum value, and a trusted time stamp data.

The invention includes a verification apparatus for verifying a time of storage of a data set stored on a data storage medium, said apparatus comprising:

a read channel for reading said data set from said data storage medium and reading an encrypted receipt data from said data storage medium;

a checksum generator for generating a first checksum value from said data set, said first checksum value substantially uniquely describing said data set;

a communications component for sending said first checksum data and said receipt data over a communications link to a trusted organization.

The invention includes a verification apparatus for verifying whether a receipt data corresponds to a data set, said apparatus comprising:

a verification component for generating a verification data depending upon a result of said comparison of said first and second checksum values, wherein if said first checksum value corresponds with said second checksum value, a positive verification data is generated, and if said first checksum value does not correspond with said second checksum value, a negative verification data is generated.

a decryptor for decrypting a receipt data containing a second checksum value and a time stamp data;

a comparing component for comparing a received first checksum value and said second checksum value;

According to a fifth aspect of the present invention there is provided a method of creating a verifiable data history comprising a plurality of data sets stored on at least one data storage medium, said method comprising:

for each said data set;

determining a checksum value of said data set, said checksum value substantially unique to said data set;

obtaining a trusted time stamp data;

forming a receipt data by applying an encryption to said checksum value and said trusted time stamp data, such that said receipt data forms an encrypted data packet;

storing said data set on a said data storage medium; and

storing said receipt data on said data storage medium.

### BRIEF DESCRIPTION OF THE DRAWINGS

For a better understanding of the invention and to show how the same may be carried into effect, there will now be described by way of example only, specific embodiments, methods and processes according to the present invention with reference to the accompanying drawings in which:

FIG. 1 illustrates schematically a host computer provided with a back up data storage device, connecting over a communications netvork to a trusted organization, for applying time stamp data to a back up data set;

FIG. 2 illustrates schematically one example of a host computer provided with a back up data storage device capable of applying a back up data format according to a specific implementation of the present invention;

FIG. 3 illustrates schematically a server computer suitable for operation by a time stamping organization, the server computer comprising time stamping and verification components for providing a receipt data, and verifying a receipt data according to the specific implementation of the present invention;

FIG. 4 illustrates schematically a data flow diagram illustrating application of a receipt data to a data set, and storage of the receipt data and data set on a back up data storage medium;

FIG. 5 illustrates schematically process steps carried out at a host computer having a data storage device and at a server computer of a verification organization, for storing a verified data set onto a back up data storage medium;

FIG. 6 illustrates schematically components of a receipt data generated by a time stamp organization, which is stored on a data storage medium along with a data set at a host computer;

FIG. 7 illustrates schematically components of a back up and verification component of a host computer equipped for seeking a time stamp receipt data from a trusted organization operating a time stamping service, and for seeking verification of a receipt data read from a stored data set on a data storage medium;

FIG. 8 illustrates schematically flow of data for verification of time and date of a data set stored on a data storage medium;

FIG. 9 illustrates schematically process steps carried out by a host verification computer of a host organization and a server computer of a verification service for verifying whether a data set stored on a back up data storage medium has a correct time and date signature; and

FIG. 10 illustrates schematically a read channel of a verification device, for example a back up data storage device or a host computer, having a verification component for verifying a data set read from a back up data storage medium.

### DETAILED DESCRIPTION OF THE BEST MODE FOR CARRYING OUT THE INVENTION

There will now be described by way of example the best mode contemplated by the inventors for carrying out the invention. In the following description numerous specific details are set forth in order to provide a thorough understanding of the present invention. It will be apparent however, to one skilled in the art, that the present invention may be practiced without limitation to these specific details. In other instances, well known methods and structures have not been described in detail so as not to unnecessarily obscure the present invention.

In the best mode implementation according to the present invention, conventional back up data storage components are augmented by addition of components to create a checksum data from a complete set of back up data that is written to a data storage medium. The back up data set is created by a conventional back up component which runs on a host computer, and copies the data set from an attached hard disk or a remote hard disk, to a back up data storage medium. The checksum data uniquely identifies the particular data set stored on the data storage medium. The checksum data may be created using a conventional hash code word creation algorithm.

A data set may comprise a plurality of data files, for example text files, spreadsheet files, program files, files of numerical data stored in text form, or the like, which are at the same time, stored on a computer or computer system contemporaneously with each other. The information in each data file may be related to information in other data files within the data set, or may be distinct and unrelated. The checksum applies to the whole intact data set. One or more data sets may exist contemporaneously with each other on an originating computer or computer system, and each data set may have a separate checksum applied thereto.

Once the checksum data has been created, the host computer system communicates with a time stamping service. The time stamping service may typically be a remote service accessed over a communications network, for example the internet, and is capable of acting as an independent trusted third party whose output is legally verifiable. The host computer :system sends the checksum to the time stamping service, and receives back a receipt which contains the checksum and a time stamp which guarantees the time at which this checksum was received by the time stamping service. The receipt is encrypted by the time stamping service to prevent tampering. This receipt is then appended to the data set on the back up data storage medium, and the data storage medium can then be removed from the host computer and placed in storage.

It is not necessary to send the complete data set to the time stamping service for verification, since the checksum value substantially uniquely identifies the data set with a high probability of certainty.

The combination of the stored data set and the receipt create a record which can be verified for integrity at any time in the future. To verify the data set, the data set is again used to create a checksum data, using the same algorithm used originally, and this is transmitted along with the receipt to a verifying organization, typically the trusted organization who originally applied the time stamp data and generated the receipt. The verifying organization decrypts the receipt to extract the original checksum and the time stamp. The verification organization compares the newly sent checksum with the checksum decrypted from the receipt, and depending upon a result of the comparison either sends back a verification message verifying that the receipt belongs to the data set, and including the time at which the original data was time stamped, or if there is a conflict, sends back a message that the data set has failed to be verified.

Components for implementation according to the best mode will now be described.

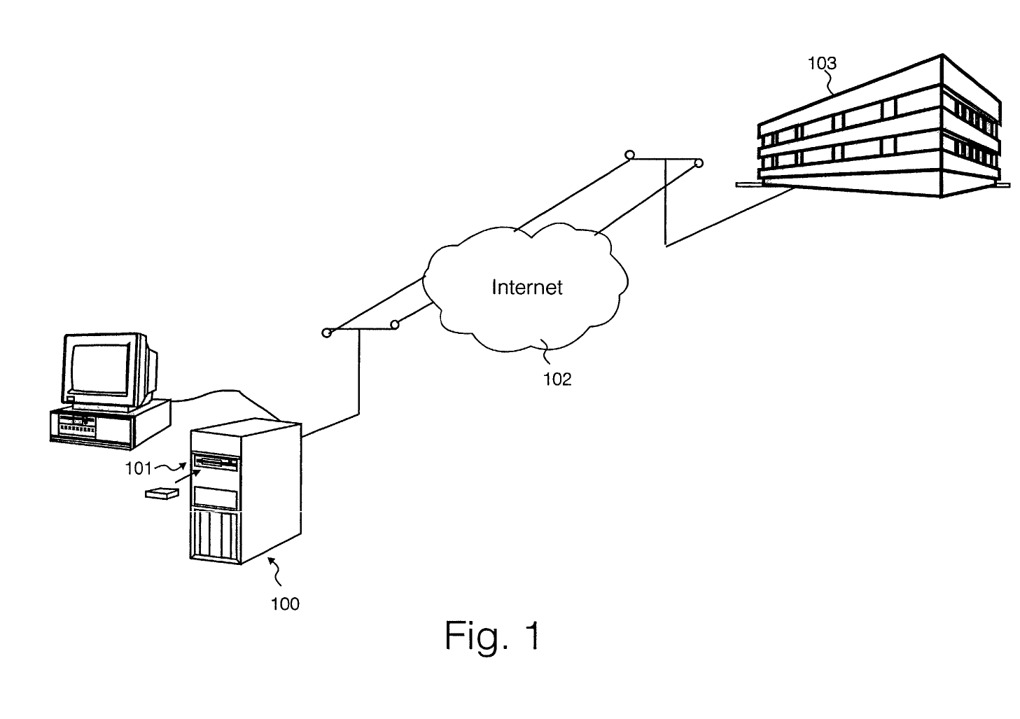

Referring to FIG. 1, there is illustrated schematically components of a verifiable data back up system for producing verifiable trusted back up data stored on a back up data storage medium at a host organization. The system comprises a host computer 100 having a back up data storage device, for example a tape drive 101; a modem for connecting to a communications network, for example the internet 102; and a trusted organization 103 equipped with one or more time stamping computer devices, set up to communicate with a plurality of host computers over the communications network and provide a time stamping service.

Typically the organization 103 providing the time stamping service, in addition to having technical capabilities for providing a reliable and verifiable time stamp data is preferably an organization of sufficient stature and standing within a business community, that the organization itself is highly trusted. Examples of the types of organizations which may provide a time stamping service include organizations having a high reputation for security and reliability, such as large banking organizations, and large security organizations A level of trustworthiness of the time stamp service organization 103 depends not only upon the technical specification of the computers and software, operated by the organization, but also upon the organizations internal security procedures, staff selection and vetting procedures, and general technical capabilities and financial stability and business reputation.

A prior art time stamping service is provided at http://www.timestamp.com.

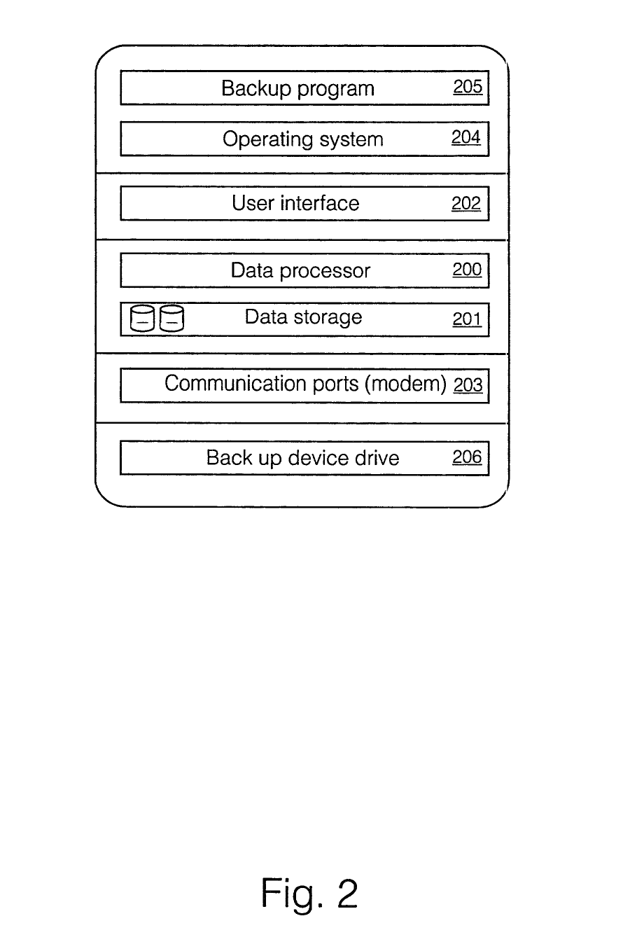

Referring to FIG. 2 herein, there is illustrated schematically components of host computer 100. The host computer comprises at least one data processor 200; one or more associated data storage devices 201; a user interface 202; one or more communications ports 203, including a modem, via which the host computer can communicate with the time stamping service; a back up device drive 204 for storing a back up data set from data storage devices 201 on to a back up data storage medium (not shown) such as a cassette tape data storage device, or CD-ROM device; an operating system 205, for example Windows 2000® Linux® or the like; and a back up program 205 for storing back up data sets to a data storage medium, and for communicating with the time stamp service for applying a verifiable receipt data received from the time stamping service to the back up data set stored on the data storage medium.

It will be appreciated by those skilled in the art that the host computer of FIG. 2 is only one of a variety of possible implementations for storing verifiable receipted back up data sets to a data storage medium according to specific methods of the present invention. In other implementations, functionality for communicating with the time stamping service may be implemented as firmware in a data storage device, such as a network attached storage device.

Further, the source of the data to be backed up, in the general case is not limited to that running on a local data storage device of the host computer running a backup program 205, but the data could be drawn from other sources, for example other computer entities attached to a same network as the host computer 100.

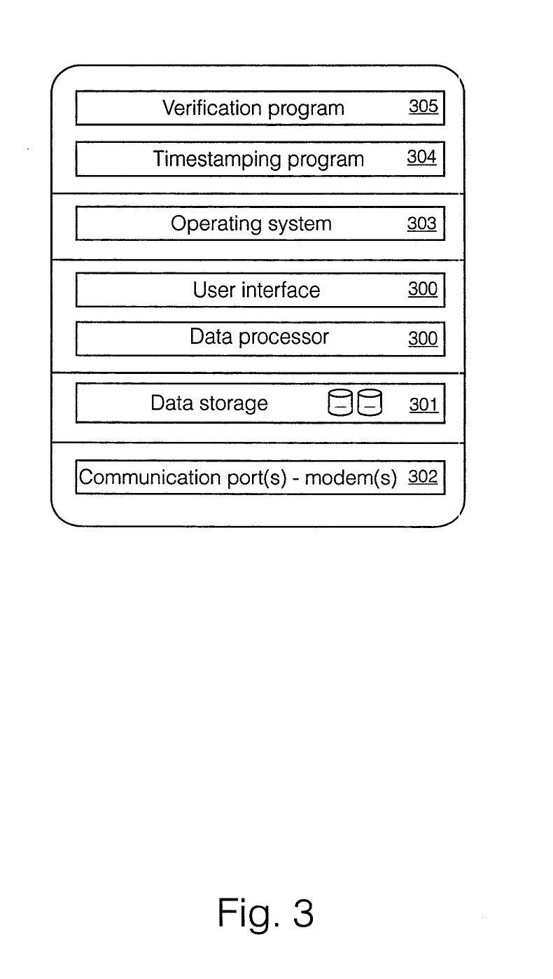

Referring to FIG. 3 herein, there is illustrated schematically a server computer operated by the trusted organization. The server computer comprises a data processor 300; one or more data storage devices 301; one or a plurality of communications ports 302, including at least one modem; an operating system 303, for example Windows 2000®, Linux®, or similar; a time stamping program 304 for receiving checksum data over a communications network, e.g. the internet, applying time stamp and date data to the checksum, encrypting the data to provide an encrypted receipt data, and sending the receipt data back to a host computer originating the check sum data; and a verification program 305 for receiving over the communications network, a checksum data and a corresponding receipt data, decrypting the receipt data to e)tract a decrypted checksum data, comparing the decrypted checksum data with the accompanying checksum data and providing a verification data verifying whether or not the receipt data corresponds with the received accompanying checksum data, and sending that verification data back to a referring computer entity.

It will be appreciated that the functionality of generating a time stamp data may be carried out on a different server computer from the function of verifying a receipt data received from a host computer. Whilst in this best mode implementation, the processes of generating a time stamp data and receipt and the process of verifying a receipt data read from a data storage medium are carried out in a same server computer in a same organization, in principle, these two functions could be carried out on separate server computers within the same time stamp organization, or on separate server computers in different organizations, provided a key data required to decode the receipt data is made available to a computer performing the verification process from the computer performing the time stamping and receipt generation process.

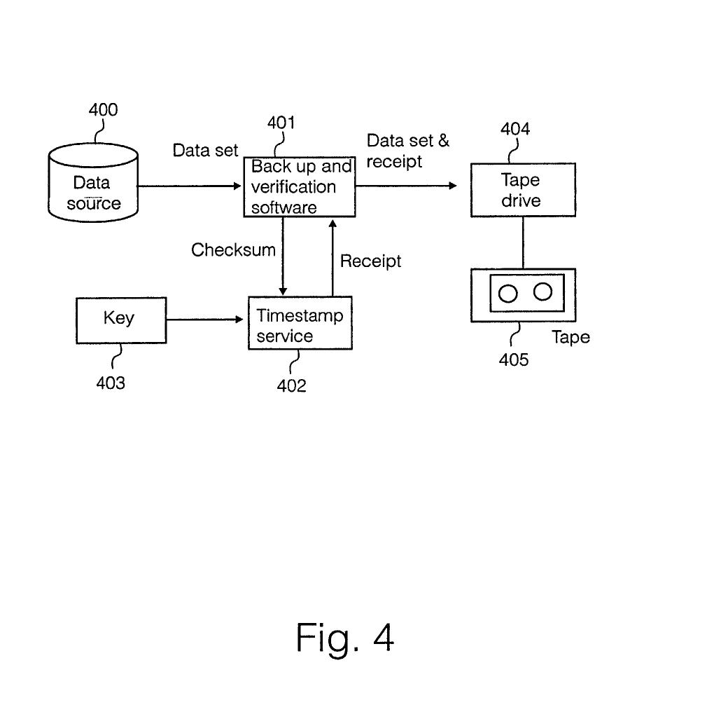

Referring to FIG. 4 herein, there is illustrated schematically a data flow diagram showing flow of data between various functional components required to apply a time stamp data and receipt to a data set. A data set comprising a number of bytes of data, for example stored on a main drive hard disk 400 of a host computer is read by back up software 401 according to a specific embodiment of the present invention. The back up software 401 generates a checksum value from the data set by applying a one way hash function to the data set. The checksum data is transmitted to a server computer 402 at a trusted service organization as hereinbefore described. At the trusted organization, a server computer generates a time stamp data. The time stamp data records at least a date, and preferably a time and date at which the data was received by the time stamp server computer. The time stamp server computer may also optionally add other information describing the trusted organization.

The receipt includes instruction data containing sufficient instructions on how to run a verification procedure to check the contents of the receipt. Encryption at the timestamp service 402 may be based upon an asymmetric key pair. Such a pair has a private key and a public key. The public key is used for encryption. A trusted third party organization always holds the matching private key, and this is the only way to decode the receipt data. The keys are generated under the control of a certificate authority, which provides full traceability and accountability for the keys.

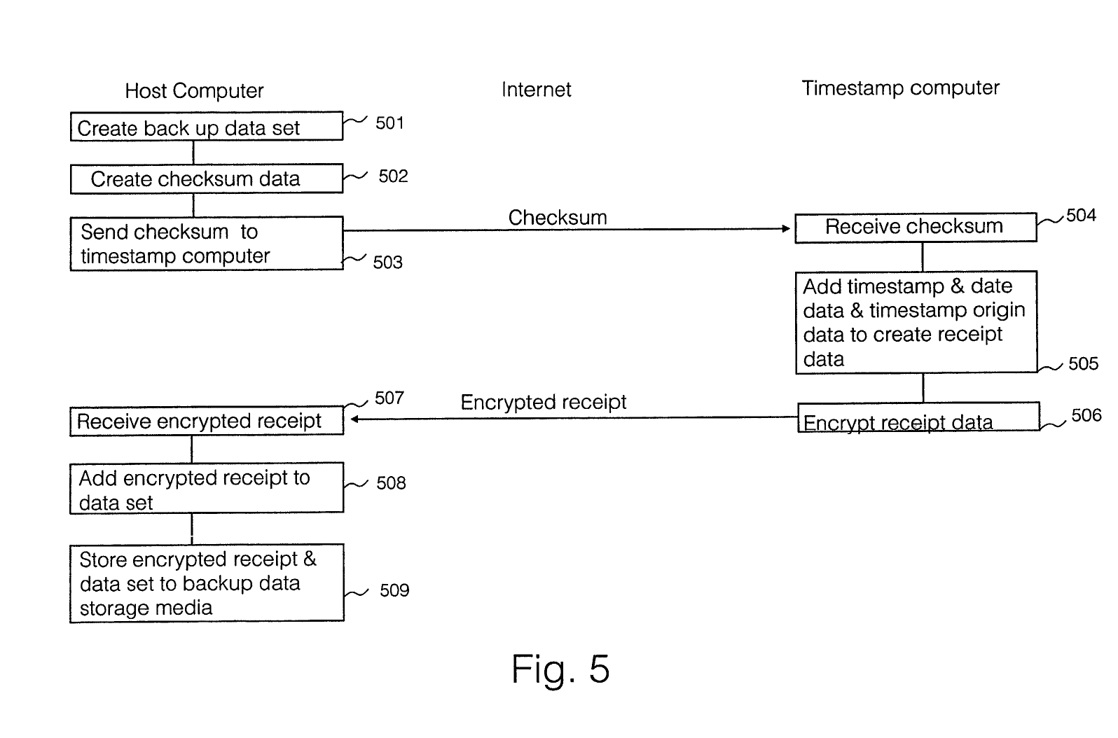

Referring to FIG. 5 herein, there is illustrated schematically process steps carried out at a host computer of a host organization for creating a back up data set and applying a receipt data to that data set, and process steps carried out at a server computer at a trusted organization for applying a time stamp data corresponding to a data set and generating a receipt data.

In step 501, the host computer creates the back up data set and in step 502, creates a checksum data. In step 503, the checksum data is sent to a server computer at the trusted organization to apply a time stamp. In step 504, the server computer receives the checksum and in step 505 adds a time stamp and date data to the received checksum. In step 506, the server computer encrypts the receipt data and sends it back to the host computer. In step 507, the host computer receives the encrypted receipt data and the back up software 401 adds the encrypted receipt data to the data set in step 508. In step 509 tape drive 404 of the host computer stores the encrypted receipt and the data set to the back up data storage medium, for example tape 405.

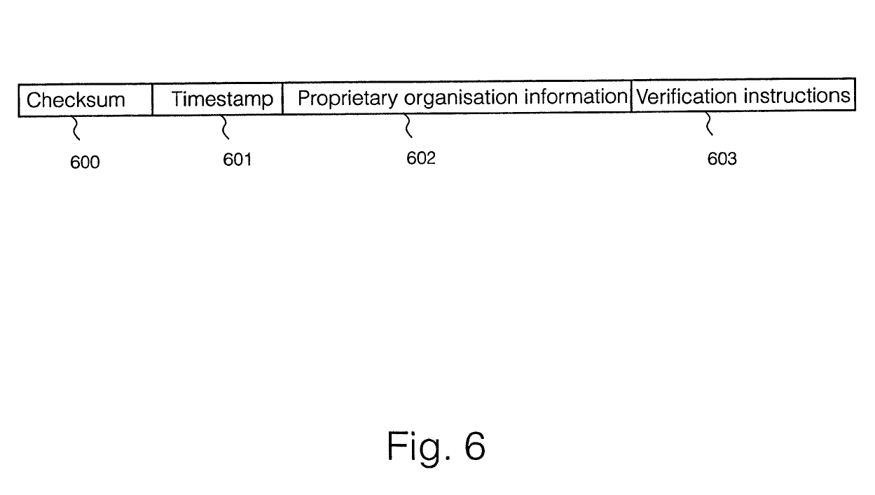

Referring to FIG. 6 herein, there is illustrated schematically components of an encrypted receipt data generated by the trusted organization. The receipt data comprises a checksum data 600, received from the host computer. Time stamp data 601 comprising at least a date data, and preferably additionally a time data at which the checksum was received by the trusted organization's server computer; a proprietary organization information 602 generated by the organization for its own reference, which may include for example, data describing a particular server computer which generated the receipt data, and referring to a particular file location on that computer where the checksum value is stored; and a verification instructions data 603, specifying how to run a verification procedure to verify the timestamp and checksum belong with each other. The receipt data is encrypted with a key data 403 in step 506 and sent back to the host computer.

The receipt contains the time stamp in a human readable format, along with a verification stamp which is created from the encoding of the checksum, time stamp, and a key data of the trusted organization.

Encryption of the receipt data is not made for purposes of secrecy, since the data being encrypted is a checksum (a series of digits), and a time/date information, which may not be particularly sensitive information. Encryption is carried out in order to avoid tampering with the receipt data, and thereby to promote trust in the receipt data.

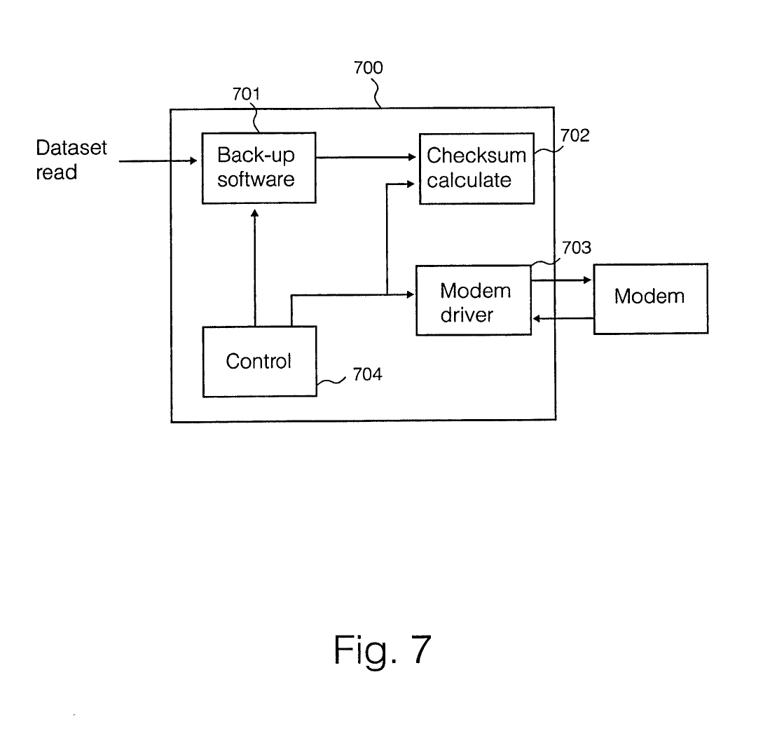

Referring to FIG. 7 herein, there is illustrated schematically components of a modified back up software 700 for storing a verified data set to a data storage medium according to a specific embodiment of the present invention. The modified back up software 700 comprises a conventional back up software 701 capable of reading a data set from a data source, for example a hard disk in a host computer, and driving a tape drive mechanism (or other data storage medium drive mechanism) for storage of the data set to the data storage medium; a checksum calculation algorithm 702 for calculating a checksum of a data set; a modem drive 703 for controlling a conventional modem to communicate with a trusted organization's computer; and a control module 704 for controlling the back up software 701, checksum calculation algorithms 702 and modem drivers 703 to obtain a receipt data, and store the receipt data and data set to a data storage medium.

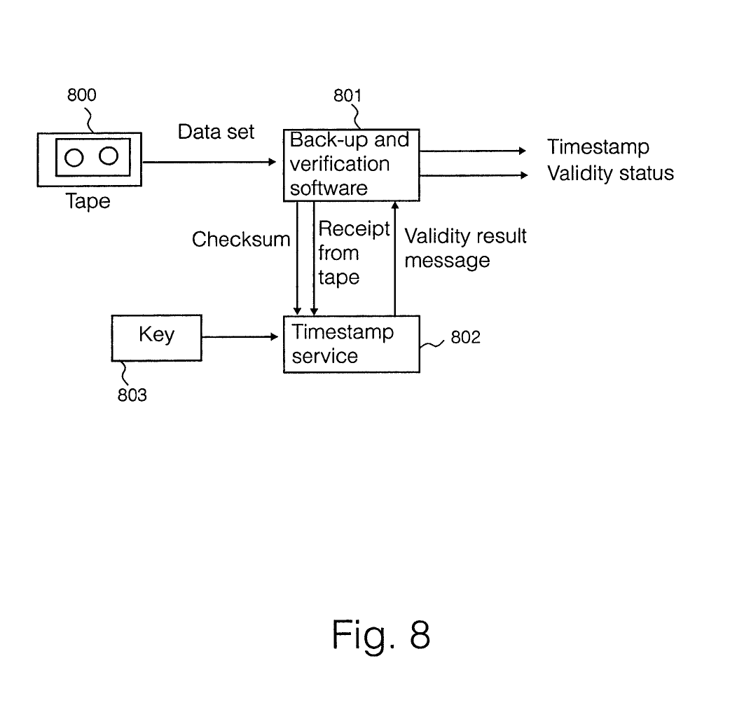

Referring to FIG. 8 herein, there is illustrated schematically a data flow diagram showing flows of data between various functional processes for verifying a time and date of creation of a data set read from a data storage medium.

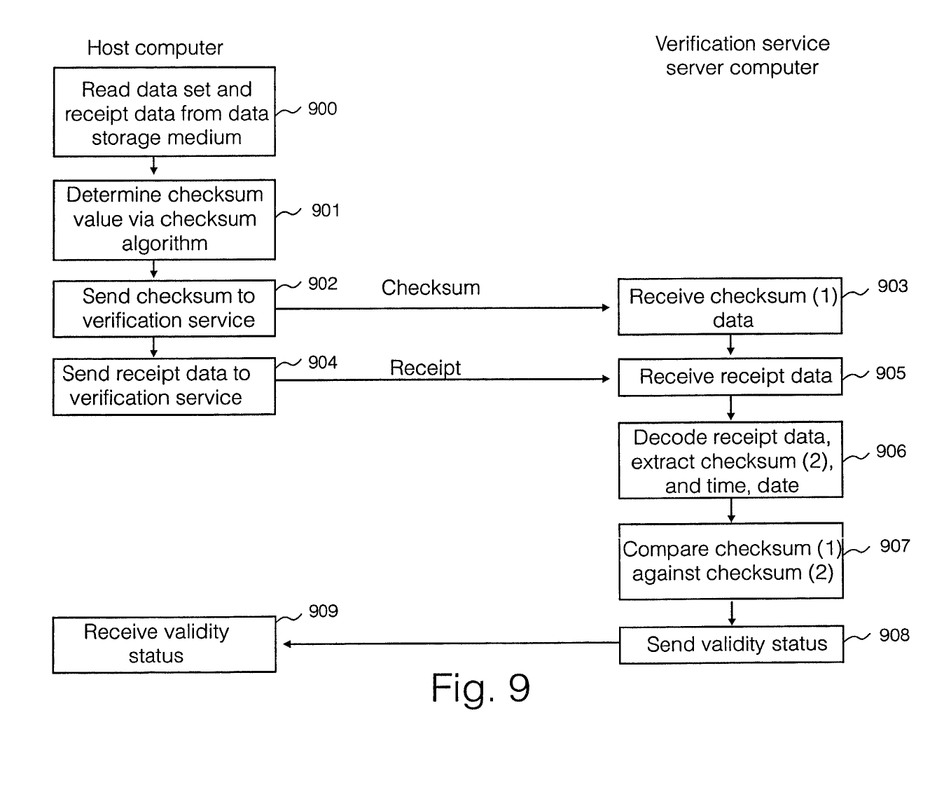

A data set is read from a data storage medium 800, along with an encrypted receipt data by the backup and verification software 801. The backup and verification software 801 sends the checksum and the encrypted receipt to a timestamp server computer 802, which applies a private key 803 to decrypt the encrypted receipt data and obtain a first checksum from the receipt, to compare with the second checksum generated by the backup and verification software 801. Further operation of the functional components shown in FIG. 8 are described with reference to FIG. 9 herein.

Referring to FIG. 9 herein, there are illustrated schematically process steps carried out by a host computer and a verification server computer operated by a trusted organization for verifying a time and date of a data set stored on a data storage medium.

In step 900 a data set is read from the data storage medium, e.g. tape 800 at the host computer, along with the receipt data by the host computers back up and verification software 801. In step 901, the back up and verification software 801 determines a checksum value of the data set recovered from the data storage medium by applying a checksum algorithm. A resultant checksum data substantially uniquely identifies the data set with a high degree of probability. In step 902, the host computer send the generated checksum to the verification server computer over a communications link, e.g. the internet via the host computers modem, controlled by modem driver 703 and control module 704. In step 903, the verification server computer receives the checksum data. In steps 904, the host computer sends the receipt data to the verification server computer over the communications network, which is received by the verification server computer in step 905. The receipt data and checksum data may be sent in a same communication. In step 906, the verification server computer decodes the receipt data using its own key. Having decoded the receipt data, the checksum contained in the receipt data is extracted, along with the time and date information, and any proprietary information 602 which may have been originally contained within the receipt data. In step 907, the verification server computer compares the first checksum value received directly from the host computer, with a second checksum value contained within the receipt data. If the two checksums value correspond (i.e. are identical) then this signifies that the data set from which the first checksum value is generated is, within a high degree of probability, identical to the data set used to originally generate the second checksum value. The degree of probability with which the two data sets from which the first and second checksum values originate are identical, depends upon the number of bits selected for the checksum value. In the best mode implementation, a checksum value of at least 32 bits is preferred in order to give a high enough probability of identity between two data sets giving rise to a same checksum value. In step 908, the verification server computer compiles a verification data which is sent as a verification result message which contains information as to whether there is an identity correspondence between the checksum value received from the host computer, and the checksum value determined from the receipt data, that is whether the receipt data corresponds to the data set which the host computer has referred to the verification server computer; a date on which the data set was generated, and optionally a time on that date, at which the data set was originally time stamped The verification result message may also contain other information identifying the trusted organization, for example a specific key and identification cede identifying the server computer within the organization. In step 909, the host computer receives the verification result message, and the operator of the host computer, having read the verification result, may store or print out that data. Computers other than the host computer can be used for verification, as long as they have access to the decryption key.

Although in the best mode implementation, the verification process of an already stored data set is shown as being carried out by the same host computer which originally requested verification of that data set, in the general case, verification can be made to any other host computer constructed as described herein, and not necessarily operated by the same host organization as the host computer from which the original data set was originally referred to the time stamp service. The processes of verification of an already stored data set may be carried out independently from the process of applying verification to a data set prior to storage on a data storage medium.

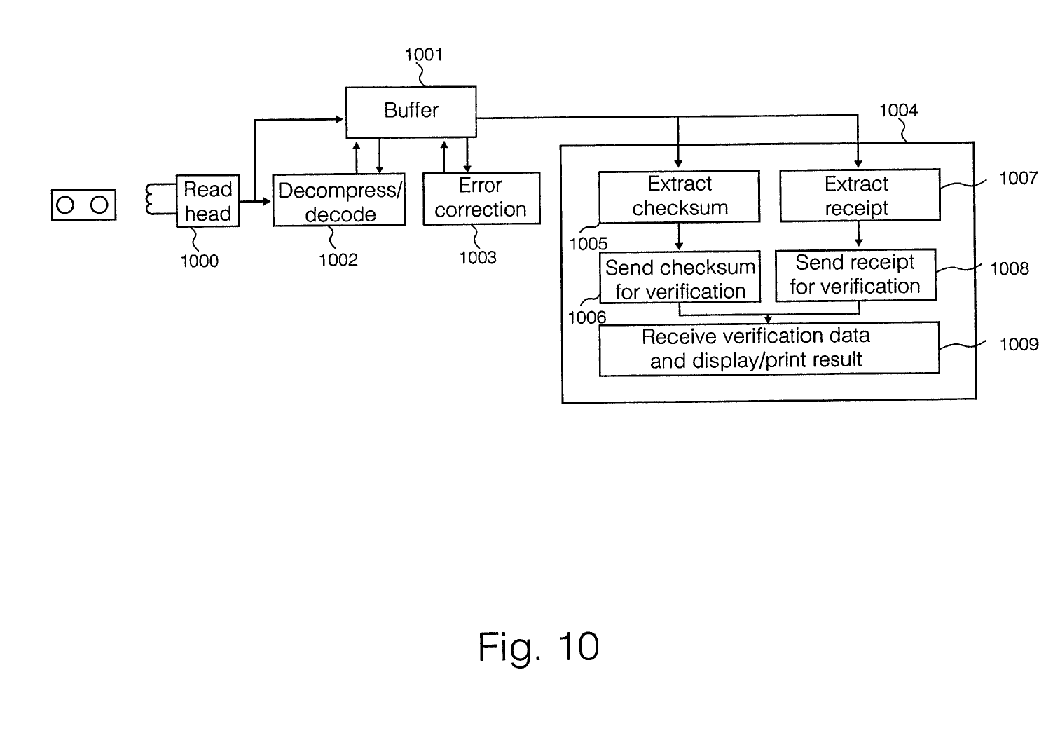

Referring to FIG. 10 herein, there is illustrated schematically components of the back up and verification software 801 in a read channel of a drive device for reading a data storage medium according to a specific implementation of the present invention. The read channel comprises a read head 1000 for reading data from the data storage medium; a buffer memory 1001 for storing a data set read from the data storage medium, along with a receipt data; a decompression/decoding algorithm 1002 for removing any decompression or redundancy coding; an error correction algorithm 1003 for correcting any errors in the read data set and receipt data; and a verification component 1004 for verifying whether the receipt data corresponds with the read data set, by sending that receipt data to a trusted computer for time stamping or verification as herein before described, the verification component 1004 comprising an extract checksum algorithm 1005 for generating a checksum from the data set stored in buffer 1001; a send checksum for verification algorithm 1006, for sending the first checksum data obtained from the data set to the time stamp/verification organization; a receipt extraction algorithm 1007 for identifying and extracting a receipt data from the buffer 1001; a send receipt for verification algorithm 1008 for forwarding the extracted receipt data to the time stamp/verification organization; and a component 1009 for receiving a verification result message from the time stamp/verification organization and allowing an operator of the host computer to display or print a result of the verification.

As described above, the specific implementations according to the present invention provide a system which generates a series of backup data sets, generated at regular time intervals according to a schedule, and/or on demand, typically exploiting and expanding on existing scheduled backups, where the data storage media can be stored as an historical record of a data development of a firm, or a project within a firm, which is verifiable after the time of its creation. Such a well documented data history may be of great value in establishing evidence in legal proceedings, or for analytical management purposes.

Whilst in the best mode herein, storage of a data set and verified receipt data is described as being written to a removable self contained data storage medium such as a backup tape data storage medium or a CD ROM. In principle, the data set and associated receipt data can be stored to any destination storage device, including a hard disk of a computer entity, or a server computer entity.

However, building up a history of data over time may be more conveniently realized by storage of data sets with encrypted receipts on individual self contained data storage medium (for example CD ROM or backup tapes) over a period of time.

The best mode implementation described herein above relies on a timestamp data generated at a timestamp organization, in other implementations, generation of the timestamp may be carried out locally within the host computer entity hosting the data storage device, or within a networked computer within the same organization as the host computer entity. In this alternative implementation, a locally generated time stamp is combined with a public key from a trusted third party organization to generate a receipt data locally. A remote verification service would still be invoked, using the private key of the remote verification service, for verification of data sets stored in this manner.

Some prior art data backup programs include integrated archive programs. These archive programs operate similarly to backup programs, but in addition to storing backup data on a data storage medium, delete the data from the source (e.g. local hard disk on a computer entity) once it has been wrilten to the backup data storage medium. The inventive methods disclosed herein apply in scenarios where archiving of data occurs with deletion of the source dal:a, as well as two scenarios where data is backed up and the original source data remains intact on a source device.

Specific implementations according the present invention may have an advantage of enabling the securing of an intact data set rather than individual documents. By capturing a record of a data set, a context relationship of individual files within the data set may be established, and information of a relationship between individual documents within a data set may be captured by virtue of capturing the whole data set.

Further, in specific implementations described herein, because data sets can be stored to a removable data storage media, with a verifiable receipt there is provided the ability to secure multiple verifiable ‘snap shots’ of a data set, by storing a series of data sets and receipts, on one or more separate data storage media forming a historical record of how a data set has developed within a computer or computer system, where each data set can be independently verified as to its date of creation, by a trusted third party. A date of creation, and the integrity of the data set as a whole may be verifiable retrospectively, after the original data set has been over written on a computer or computer system on which it was originally created.

1. A method of storing a data set to a data storage medium, said method comprising:
determining a checksum value of said data set, said checksum value being substantially unique to said data set;
obtaining a trusted time stamp data;
forming a receipt data by applying an encryption to said checksum value and said trusted time stamp data, such that said receipt data forms an encrypted data packet;
storing said data set on a said data storage medium; and
storing said receipt data on said data storage medium:

2. The method as claimed in claim 1, wherein said checksum value comprises a one way hash function of said data set.

3. The method as claimed in claim 1, wherein said step of obtaining a trusted time stamp data comprises:
sending said checksum value over a communications network to a trusted computer for addition of said trusted time stamp data.

4. The method as claimed in claim 1, further comprising:
receiving over a communications network said receipt data.

5. A method for verifying a time of storage of a data set stored on a data storage medium, said method comprising:
reading said data set from said data storage medium;
determining a first checksum data from said data set, said first checksum data substantially uniquely describing said data set;
extracting an encrypted receipt data from said data storage medium;
decrypting said receipt data to obtain a second checksum data, and a time data;
comparing said first checksum data with said second checksum data; and
if said second checksum data corresponds with said first checksum data, generating a verification data verifying that said time data corresponds with said data set.

6. The method as claimed in claim 5, wherein said step of extracting said second checksum data and time stamp data are performed by a trusted computer.

7. The method as claimed in claim 5, wherein said step of comparing said first and second checksum data is carried out by a trusted computer.

8. A method of storing a data set to a data storage medium, said method comprising: determining a checksum value of said data set, said checksum value being substantially unique to said data set;
storing said data set on said data storage medium;
storing a receipt data to said data storage medium, said receipt data comprising said checksum value, and a trusted time stamp data.

9. The method as claimed in claim 8, wherein said receipt data is encrypted.

10. A method of verifying a time of storage of a data set stored on a data storage medium, said method comprising:
reading said data set from said data storage medium;
determining a first checksum value from said data set, said first checksum value substantially uniquely describing said data set;
reading an encrypted receipt data from said data storage medium;
sending said first checksum data and said receipt data to a trusted computer.

11. The method as claimed in claim 9, further comprising:
receiving a verification result data from said trusted computer, said result message comprising:
a time stamp data extracted from said receipt data;
an identity data, identifying whether or not said receipt data corresponds to said determined first checksum data.

12. A method of verifying whether a receipt data corresponds to a data set, said method comprising:
receiving a first checksum value, said first checksum value substantially uniquely describing said data set;
receiving a receipt data containing a second checksum value and a time stamp data;
comparing said first checksum value and said second checksum value;
generating a verification data depending upon a result of said comparison of said first and second checksum values, wherein if said first checksum value corresponds with said second checksum value, a positive verification data is generated, and if said first checksum value does not correspond with said second checksum value, a negative verification data is generated.

13. The method as claimed in claim 12, further comprising the step of:
if said first checksum value corresponds with said second checksum value, verifying that said time stamp data corresponds with said data set.

14. The method as claimed in claim 12, wherein, said receipt data is received in encrypted format, and further comprising the step of decrypting said receipt data using a locally stored key data.

15. A data storage system for storing a data set to a data storage medium, said system comprising:
a checksum generator for generating a checksum value of said data set, said checksum value substantially unique to said data set;
a trusted time stamp generator for generating a trusted time stamp data;
a receipt generator for forming a receipt data by applying an encryption to said checksum value and said trusted time stamp data, such that said receipt data forms an encrypted data packet; and
a write channel for storing said data set on a said data storage medium and storing said receipt data on said data storage medium.

16. The system as claimed in claim 15, wherein said checksum generator comprises a hash function generator for generating a one way hash function of said data set.

17. The system as claimed in claim 15, wherein:
said trusted time stamp generator is operated by a trusted organization.

18. A system for verifying a time of storage of a data set stored on a data storage medium, said system comprising:
a read channel for reading said data set from said data storage medium;
a checksum generator for generating a first checksum data from said data set, said first checksum data substantially uniquely describing said data set, said read channel operable to read an encrypted receipt data from said data storage medium;
a decryptor for decrypting said receipt data to obtain a second checksum data, and a time data;
a compare component for comparing said first checksum data with said second checksum data; and
a verification data generator operable such that if said second checksum data corresponds with said first checksum data, said verification data generator generates a verification data verifying that said time data corresponds with said data set.

19. The system as claimed in claim 18, wherein said decryptor operates within a trusted environment.

20. The system as claimed in claim 18, wherein said compare component for comparing said first and second checksum data operates in a trusted environment.

21. A data storage device for storing a verified data set to a data storage medium, said device comprising:
a checksum generator for generating a checksum value of said data set, said checksum value substantially unique to said data set; and
a write channel for storing said data set on said data storage medium; and
storing a receipt data to said data storage medium, said receipt data comprising said checksum value, and a trusted time stamp data.

22. A verification apparatus for verifying a time of storage of a data set stored on a data storage medium, said apparatus comprising:
a read channel for reading said data set from said data storage medium and reading an encrypted receipt data from said data storage medium;
a checksum generator for generating a first checksum value from said data set, said first checksum value substantially uniquely describing said data set;
a communications component for sending said first checkcum data and said receipt data over a communications link to a trusted organization.

23. The apparatus as claimed in claim 22, further comprising:
a component for receiving a verification result message from said trusted organization, said result message comprising:
a time stamp data extracted from said receipt data;
an identification data, verifying whether or not said receipt data corresponds to said determined first checksum data.

24. A verification apparatus for verifying whether a receipt data corresponds to a data set, said apparatus comprising:
a verification component for generating a verification data depending upon a result of said comparison of said first and second checksum values, wherein if said first checksum value corresponds with said second checksum value, a positive verification data is generated, and if said first checksum value does not correspond with said second checksum value, a negative verification data is generated.
a decryptor for decrypting a receipt data containing a second checksum value and a time stamp data;
a comparing component for comparing a received first checksum value and said second checksum value;

25. The apparatus as claimed in claim 24, wherein said verification component operates to:
verify that said time stamp data corresponds with said data set if said first checksum value corresponds with said second checksum value.

26. A method of creating a verifiable data history comprising a plurality of data sets stored on at least one data storage medium, said method comprising:
for each said data set;
determining a checksum value of said data set, said checksum value substantially unique to said data set;
obtaining a trusted time stamp data;
forming a receipt data by applying an encryption to said checksum value and said trusted time stamp data, such that said receipt data forms an encrypted data packet;
storing said data set on a said data storage medium; and
storing said receipt data on said data storage medium.

27. The method as claimed in claim 6, wherein said trusted time stamp data is obtained from an on-line source.

28. A method of storing a data set and a receipt data relating to said data set to a data storage medium, said method comprising:
determining a checksum value of said data set, said checksum value being substantially unique to said data set;
obtaining a trusted time stamp data;
forming a receipt data by applying an encryption to said checksum value and said trusted time stamp data, such that said receipt data forms an encrypted data packet;
storing said data set on a said data storage medium; and
storing said receipt data on said data storage medium.

29. A data storage system for storing a data set to a removable data storage medium, said system comprising:
a checksum generator for generating a checksum value of said data set, said checksum value substantially unique to said data set;
a trusted time stamp generator for generating a trusted time stamp data;
a receipt generator for forming a receipt data by applying an encryption to said checksum value and said trusted time stamp data, such that said receipt data forms an encrypted data packet; and
a write channel for storing said data set and storing said receipt data on said removable data storage medium.

30. A system for verifying a time of storage of a data set stored on a removable data storage medium, said system comprising:
a read channel for reading said data set from said removable data storage medium;
a checksum generator for generating a first checksum data from said data set, said first checksum data substantially uniquely describing 3aid data set, said read channel operable to read an encrypted receipt data from said removable data storage medium;
a decryptor for decrypting said receipt data to obtain a 3econd checksum data, and a time data;
a compare component for comparing said first checksum data with said second checksum data; and
a verification data generator operable such that if said second checksum data corresponds with said first checksum data, said verification data generator generates a verification data verifying that said time data corresponds with said data set.

31. A data storage device for storing a verified data set to a removable data storage medium, said device comprising:
a checksum generator for generating a checksum value of said data set, said checksum value being substantially unique to said data set; and
a write channel for storing said data set on said removable data storage medium; and
a store for storing a receipt data to said removable data storage medium, said receipt data comprising said checksum value, and a trusted time stamp data.
